(19) United States
(12) Patent Application Publication
(10) Pub. No.: US 2026/0344512 A1
(43) Pub. Date: Oct. 29, 2026

(54) SEMICONDUCTOR STRUCTURE INCLUDING PAD FEATURE AND METHOD FOR MANUFACTURING THE SAME

(71) Applicant: TAIWAN SEMICONDUCTOR MANUFACTURING COMPANY, LTD., Hsinchu (TW)

(72) Inventors: Chia-Hua LIN, Hsinchu (TW); Hai-Dang TRINH, Hsinchu (TW); Cheng-Tai HSIAO, Hsinchu (TW)

(73) Assignee: TAIWAN SEMICONDUCTOR MANUFACTURING COMPANY, LTD., Hsinchu (TW)

(21) Appl. No.: 19/189,928

(22) Filed: Apr. 25, 2025

(51) Int. Cl. H10W 90/00; H10P 74/20; H10W 72/00; H10W 72/90; H10W 80/00

(52) U.S. Cl. CPC H10W 90/00; H10P 74/207; H10W 72/01908; H10W 72/01938; H10W 72/01951; H10W 72/01953; H10W 72/987; H10W 80/312; H10W 80/327; H10W 90/792

(57) ABSTRACT

A method for manufacturing a semiconductor structure includes: forming a base structure which includes a device region and an interconnect structure formed over the device region, the interconnect structure including interconnect layers formed in a dielectric layer and connected to the device region; forming a passivation structure on the interconnect structure; forming a conductive pad which extends through the passivation structure so that the conductive pad is connected to a first portion of the interconnect layers; performing an electrical test on the base structure through the conductive pad; performing a pad-processing treatment on the conductive pad to form a pad feature in the passivation structure; forming a dielectric portion on the passivation structure and the pad feature; and forming a conductive portion which extends through the dielectric portion and the passivation structure so that the conductive portion is connected to a second portion of the interconnect layers.

### BACKGROUND

With dramatic advances in semiconductor technology, the dimension of semiconductor devices, such as metal oxide semiconductor field effect transistors (MOSFETs) is continuously scaled down, and the MOSFETs may be stacked vertically to form a three-dimensional integrated circuit (3DIC) with reduced power consumption and smaller footprint compared to conventional two-dimensional processes, so as to achieve improvement in performance. The concept of 3DIC applies not only to the local (transistor) level, but also to the intermediate (bond pad) level and the global (package) level. Wafer bonding or wafer stacking is a 3D packaging technology for stacking multiple wafers together, and is still undergoing vigorous development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 21 illustrate schematic views of intermediate stages of the method depicted in FIG. 1 in accordance with some embodiments.

FIG. 22 is a graph illustrating the variation of wafer bow under different processes for different samples for forming the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects +5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

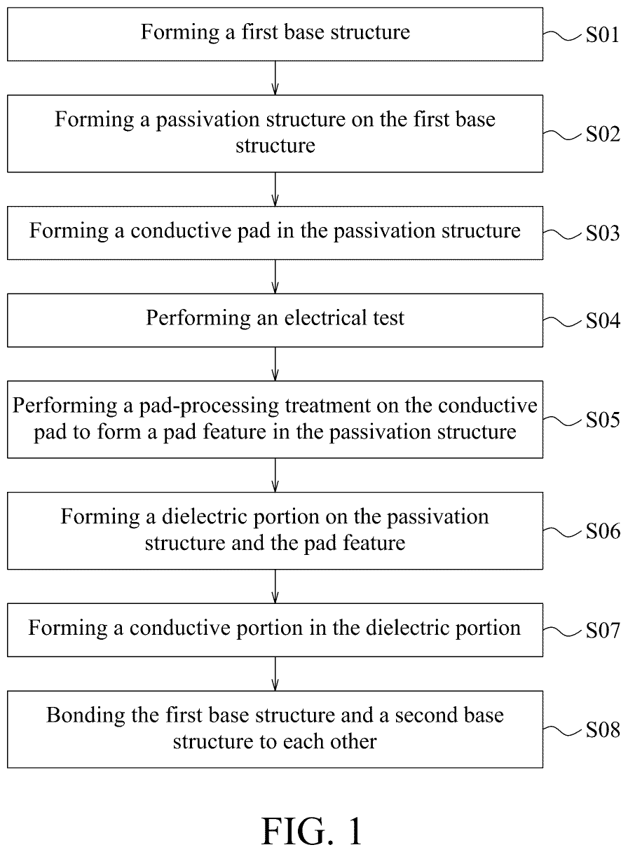

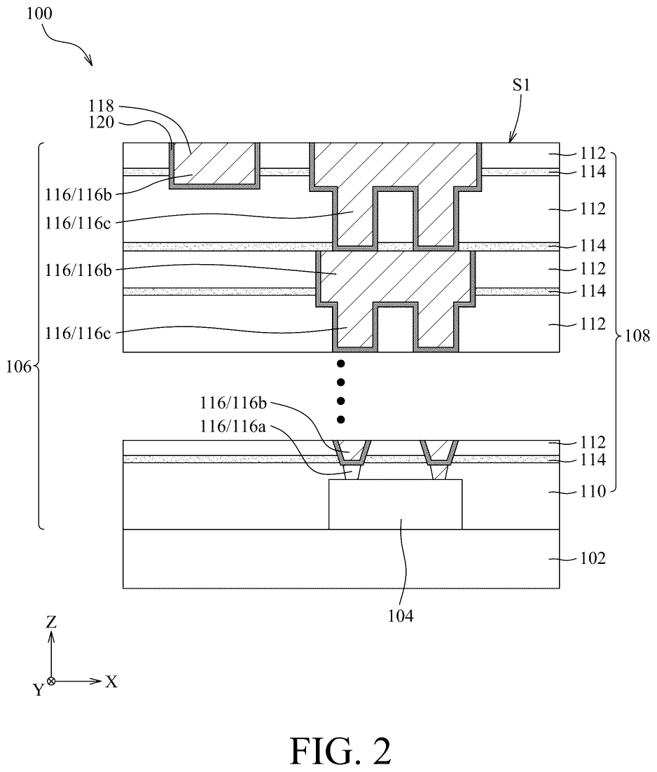

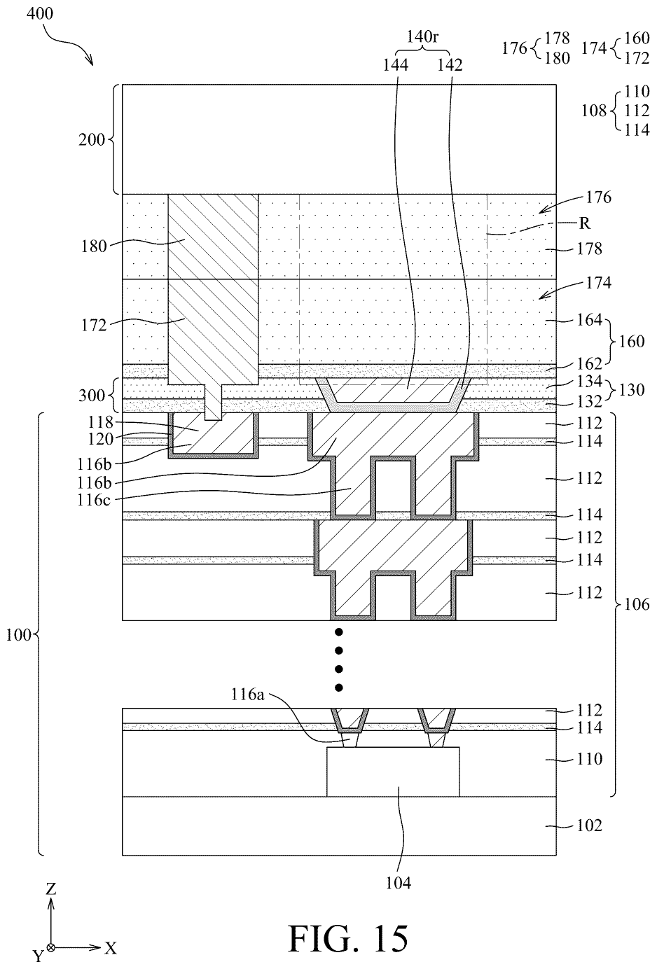

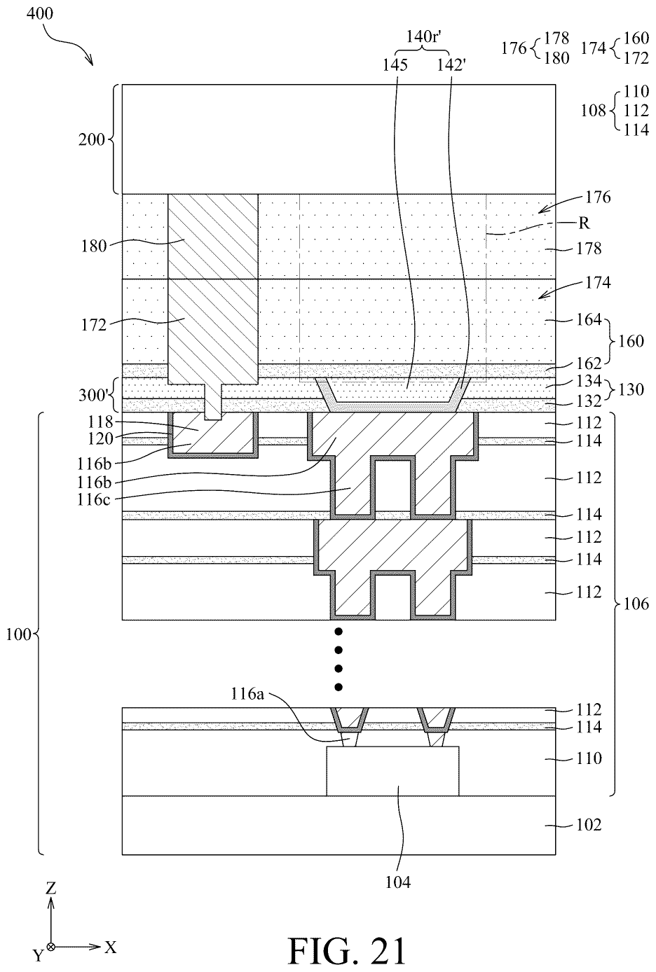

FIG. 1 is a flow diagram illustrating a method for manufacturing a semiconductor structure (for example, but not limited to, a semiconductor structure 400 shown in FIG. 15 or FIG. 21) in accordance with some embodiments. The method may include steps S01 to S08. FIGS. 2 to 21 illustrate schematic views of intermediate stages of the method in accordance with some embodiments, and the structures shown in FIGS. 2 to 21 are obtained by the steps that are also illustrated in the flow diagram of FIG. 1. Some repeating structures are omitted in FIGS. 2 to 21 for the sake of brevity. Additional steps can be provided before, after or during the method, and some of the steps described herein may be modified, replaced by other steps, or eliminated without departure from the spirit and scope of the present disclosure.

In advanced semiconductor technologies, two different chips or wafers may be bonded to each other by a bonding process (e.g., a die-to-die bonding, a die-to-wafer bonding, a wafer-to-wafer bonding) to form a semiconductor bonded structure. In some embodiments, the electrical performance of the chips or the yield rate of the wafers may be determined or verified before the bonding process, so as to select the chips or wafers that are suitable for the subsequent bonding process, thereby increasing the yield rate of the semiconductor bonded structure.

FIG. 2 is a schematic sectional view illustrating a first base structure 100 in a first semiconductor chip in accordance with some embodiments. In some embodiments, the first semiconductor chip may be one of chips on a first wafer (the first wafer is not singulated), or a chip that is singulated from the first wafer. The structure shown in FIG. 2 is obtained after step S01 of the method as shown in FIG. 1.

The first base structure 100 includes a substrate 102, a device region 104 formed on the substrate 102, and an interconnect structure 106 formed over the device region 104 in a Z direction which is normal to the substrate 102.

In some embodiments, the substrate 102 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 102 may be a bulk semiconductor substrate, for example, but not limited to, a bulk substrate of silicon, germanium, silicon germanium, or other suitable semiconductor materials (such as the examples described earlier in the same paragraph). In some embodiments, the substrate 102 may be formed with an n-type well having an n-type conductivity and a p-type well having a p-type conductivity. Each of the n-type well and the p-type well may be formed by introducing an n-type impurity or a p-type impurity into the substrate 102 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the substrate 102 may be configured as a semiconductor-on-insulator substrate. Other suitable materials and configurations for the substrate 102 are within the contemplated scope of the present disclosure.

In some embodiments, the device region 104 includes a logic circuitry with transistors, a memory circuitry having memory devices, passive devices, and/or other suitable functional devices. In some embodiments, the transistors may include a planar transistor, a fin-type field-effect transistor (FinFET), a gate-all-around (GAA) transistor, a complementary field-effect transistor (CFET) which includes a lower GAA transistor and an upper GAA transistor sequentially formed over the substrate 102, a fork-sheet transistor which includes two GAA transistors spaced part from each other through a wall portion which is formed on a trench isolation, other transistors having suitable three-dimensional configurations, or combinations thereof.

In some embodiments, the interconnect structure 106 includes a dielectric portion 108 and interconnect layers 116. The interconnect layers 116 are disposed in the dielectric portion 108 and electrically connected to each other. In some embodiments, the dielectric portion 108 may include at least one inter-layer dielectric (ILD) layer 110 disposed over the device region 104, inter-metal dielectric (IMD) layers 112 disposed on the at least one ILD layer 110, and etch stop layers 114 which are disposed to alternate with the IMD layers 112. In some embodiments, the at least one ILD layer 110 and the IMD layers 112 are interleaved by the etch stop layers 114. In some embodiments, a thickness of a bottommost one of the IMD layers 112 is less than a thickness of at least one of the IMD layers 112 above the bottommost one of the IMD layers 112. In some embodiments, the bottommost one of the IMD layers 112 and the at least one of the IMD layers 112 above the bottommost one of the IMD layers 112 are respectively proximate to and distal from the device region 104. In some embodiments, each of the at least one ILD layer 110 and the IMD layers 112 includes or is made of a low-k dielectric material. In some embodiments, each of the at least one ILD layer 110 and the IMD layers 112 includes or is made of silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. In some embodiments, each of the etch stop layers 114 includes or is made of a dielectric material that is different from the dielectric material of a corresponding one of the at least one ILD layer 110 and the IMD layers 112 that is located therebeneath, so that each of the etch stop layers 114 may serve as an etch stop point during formation of the interconnect layers 116. In some embodiments, possible dielectric materials suitable for each of the etch stop layers 114 include silicon nitride, silicon oxide, silicon oxynitride, silicon oxycarbide, silicon carbonnitride, metal oxide (which includes oxides of, for example, but not limited to, aluminum, zirconium, hafnium, or combinations thereof), metal nitride, metal oxynitride, metal oxycarbide, metal oxycarbon nitride, other suitable dielectric materials, or combinations thereof.

In some embodiments, the interconnect layers 116 may be collectively referred to as a conductive portion. Each of the interconnect layers 116 includes conductive features (still denoted by the reference numeral 116). The conductive features 116 may be configured as conductive contacts 116a which are formed in the at least one ILD layer 110, conductive lines 116b (which may also be referred to as metal lines) which are formed in the IMD layers 112, or conductive vias 116c which are formed in the IMD layers 112. Each of the conductive contacts 116a are electrically connected between the device region 104 and a corresponding one of the conductive lines 116b. Each of the conductive vias 116c is configured to be connected between an upper one of the conductive lines 116b and a lower one of the conductive lines 116b. In some embodiments not shown herein, at least one of the conductive lines 116b includes a curved top surface. The curved top surface is above a top surface of a corresponding one of the IMD layers 112 that is formed around at least one of the conductive lines 116b. In some embodiments, each of the conductive features 116 includes a conductive filling portion 118 and a barrier layer 120 disposed to separate the conductive filling portion 118 from the dielectric portion 108. In some embodiments, the barrier layer 120 may be used to prevent metal atoms of the conductive filling portion 118 from diffusing into the dielectric portion 108. In some embodiments, the conductive filling portion 118 includes or is made of Co, Cu, Ru, W, Mo, Ti, Al, Ir, Rh, alloys thereof, graphene, or combinations thereof. In some embodiments, the barrier layer 120 includes or is made of tantalum, tantalum nitride, titanium, titanium nitride, manganese nitride, ruthenium, ruthenium nitride, aluminum, aluminum nitride, cobalt, cobalt nitride, cobalt tungsten, molybdenum, molybdenum nitride, tungsten nitride, iridium, iridium nitride, rhodium, rhodium nitride, graphene, or combinations thereof. In some embodiments, the barrier layer 120 has an electrical conductivity that is less than an electrical conductivity of the conductive filling portion 118. In some embodiments, the interconnect structure 106 may be formed by dual damascene processes, single damascene processes, or other suitable back-end-of-line (BEOL) techniques.

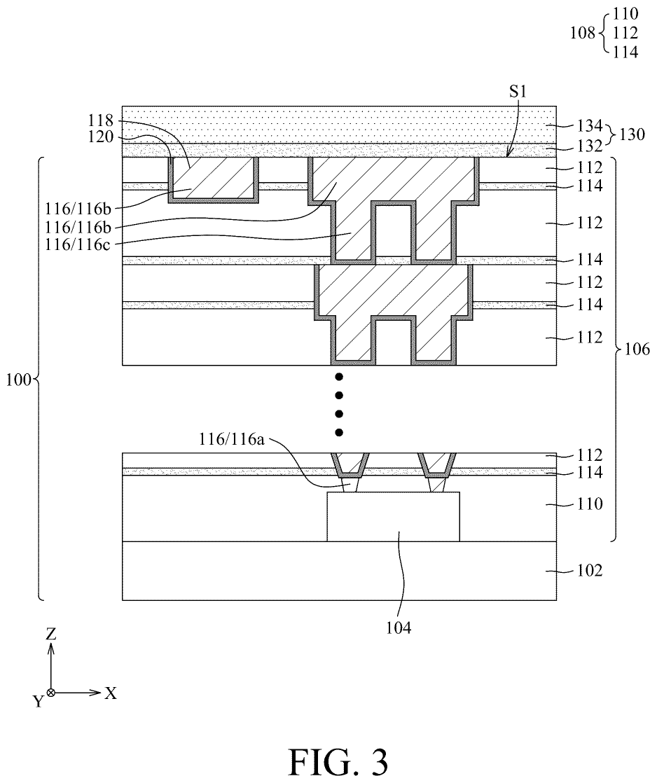

The interconnect structure 106 has an upper surface S1 distal from the device region 104. In some embodiments, a farthest one of the interconnect layers 116 relative to the device region 104 is exposed from the dielectric portion 108, and has a portion of the upper surface S1 of the interconnect structure 106. In some embodiments, the conductive features 116 in the farthest one of the interconnect layers 116 is configured as conductive lines 116b (two of which are exemplarily shown in, for example, FIG. 3).

In the following description, the conductive lines 116b refer to the conductive lines in the farthest one of the interconnect layers 116 (that is, the conductive lines exposed from the dielectric portion 108 and having the portion of the upper surface S1 of the interconnect structure 106 as shown in FIG. 2). In some embodiments, the two conductive lines 116b may represent two different conductive lines that are separated from each other by a corresponding one of the IMD layers 112 that is disposed around the two conductive lines 116b. In some embodiments, the two conductive lines 116b may represent two portions of a single conductive line. In some embodiments, the conductive lines 116b extends lengthwise along a Y direction transverse the Z direction. In some embodiments, the conductive lines 116b may have widths (measured along an X direction transverse to the Y and Z directions) the same as or different from each other. In some embodiments, the X, Y and Z directions are perpendicular to each other.

Referring to FIG. 3, a passivation structure 130 is formed on the upper surface S1 of the interconnect structure 106 by chemical vapor deposition (CVD), atomic layer deposition (ALD), or other suitable deposition techniques. The passivation structure 130 may be configured as a single layer structure or a multi-layered structure. In some embodiments, the passivation structure 130 includes a first dielectric layer 132 formed on the interconnect structure 106 and a second dielectric layer 134 formed on the dielectric layer 132 opposite to the interconnect structure 106. In some embodiments, a dielectric constant of the dielectric layer 132 is greater than a dielectric constant of the dielectric layer 134. Since possible dielectric materials suitable for the dielectric layer 132 are similar to those for forming the etch stop layers 114, and possible dielectric materials suitable for the dielectric layer 134 are similar to those for forming the ILD layer 110 and the IMD layer 112, details thereof are omitted for the sake of brevity. The structure shown in FIG. 3 is obtained after step S02 of the method as shown in FIG. 1.

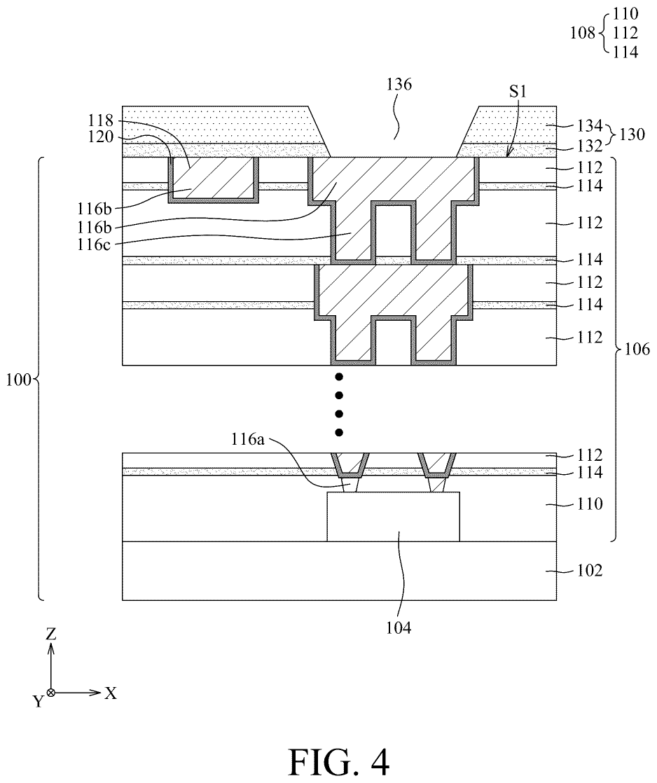

Referring to FIG. 4, the passivation structure 130 is patterned by a patterning process to form at least one opening 136 (one of which is exemplarily shown in, for example, FIG. 4) in the passivation structure 130, such that at least one of the conductive features 116b (for example, a right one of the conductive lines 116b shown in FIG. 4) is exposed to the at least one opening 136, respectively.

In some embodiments, the patterning process includes a photolithography process and a subsequent etching process. The photolithography process may include: forming a photoresist layer over a structure to be patterned by, for example, a spin coating process; and patterning the photoresist layer by, for example, an exposure process using a photomask and a development process. The etching process, which utilizes the patterned photoresist layer as an etching mask, may include etching the structure to be patterned by, for example, dry etching, wet etching, or a combination thereof. In the following description, a patterning process, a photolithography process or an etching process, unless otherwise stated or defined in this disclosure, may be performed in a way similar to the above-mentioned ones.

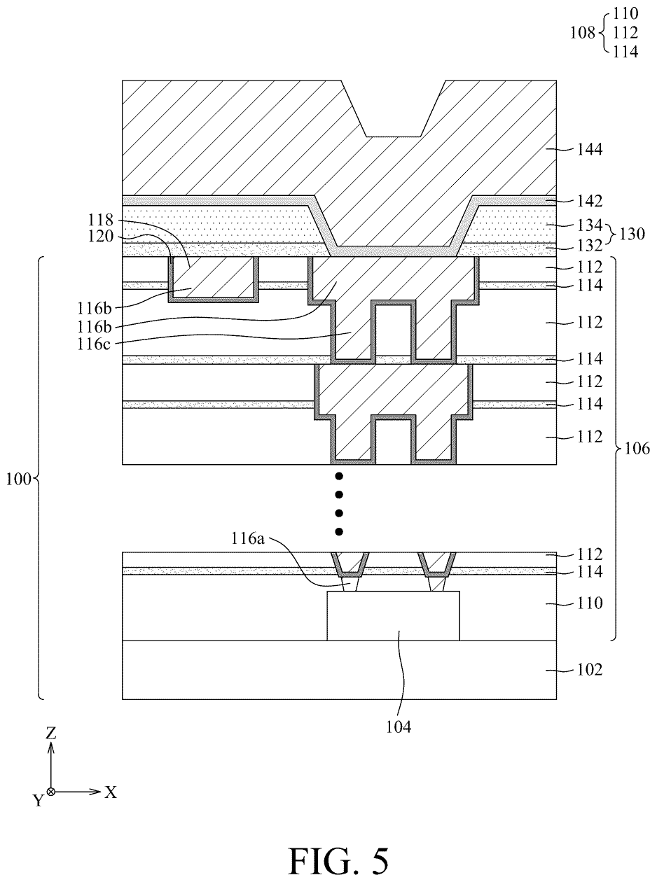

Referring to FIG. 5, a barrier layer 142 is formed along an upper surface of the passivation structure 130 and along an inner surface of the opening 136 (see FIG. 4), and a conductive layer 144 is formed on the barrier layer 142 to fill the opening 136. The barrier layer 142 has an electrical conductivity that is less than an electrical conductivity of the conductive layer 144. Since possible materials suitable for the barrier layer 142 are similar to those for forming the barrier layer 120, and possible conductive materials suitable for the conductive layer 144 are similar to those for forming the conductive filling portion 118, details thereof are omitted for the sake of brevity. In some embodiments, the barrier layer 142 may be formed by CVD, ALD, physical vapor deposition (PVD), or other suitable deposition techniques. In some embodiments, the conductive layer 144 may be formed by CVD, ALD, PVD, an electroplating process, an electroless-plating process, or other suitable deposition techniques.

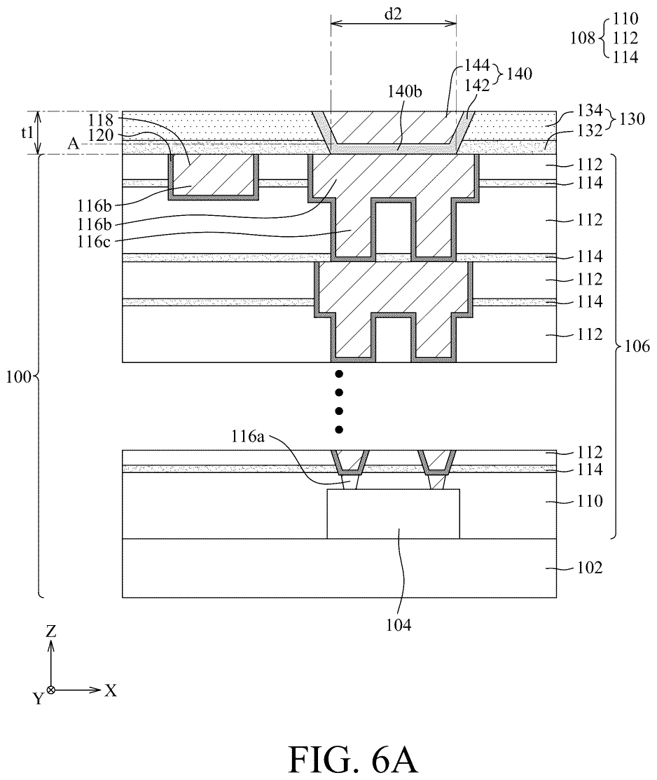

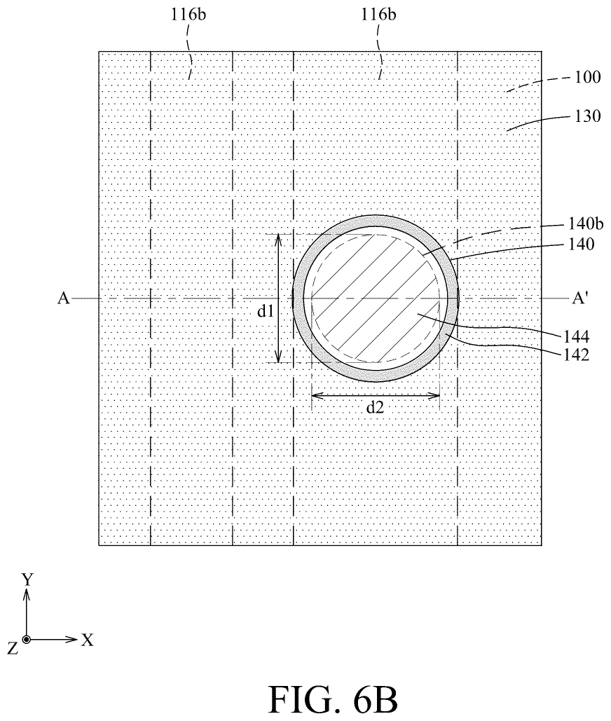

Next, a first planarization process is performed on the conductive layer 144 and the barrier layer 142 until the passivation structure 130 is exposed, such that the conductive layer 144 and the barrier layer 142 are respectively formed into a barrier portion (still denoted by the reference numeral 142) and a conductive filling portion (still denoted by the reference numeral 144), as shown in FIG. 6A. The barrier portion 142 and the conductive filling portion 144 collectively constitute a conductive pad 140. The conductive pad 140 is used for the purpose of verification, such as an electrical test in a subsequent step (step S04). The conductive pad 140 extends through the passivation structure 130 so as to be electrically connected to the right one of the conductive lines 116b. The structure shown in FIG. 6A is obtained after step S03 of the method as shown in FIG. 1.

FIG. 6B is a schematic top view of the structure shown in FIG. 6A in accordance with some embodiments, and illustrates the passivation structure 130, the conductive pad 140, a bottom portion 140b of the conductive pad 140, and the conductive lines 116b that are located immediately beneath the passivation structure 130 along the Z direction. FIG. 6A is a schematic sectional view taken along line A-A′ of FIG. 6B in accordance with some embodiments, and further illustrates the components that are omitted in FIG. 6B.

The right one of the conductive lines 116b has a length along the Y direction and a width along the X direction. The bottom portion 140b of the conductive pad 140 has a first dimension (d1) along the Y direction and a second dimension (d2) along the X direction. The first dimension (d1) is less than the length of the conductive line 116b, and the second dimension (d2) is not greater than the width of the conductive line 116b. In some embodiments, as shown in FIG. 6B, a projection of the conductive pad 140 on the base structure 100 has a circular shape. In some embodiments not shown herein, the projection of the conductive pad 140 on the base structure 100 may have a rounded shape, an elliptical shape, an obround shape, a square shape, a rectangular shape, or other suitable shapes.

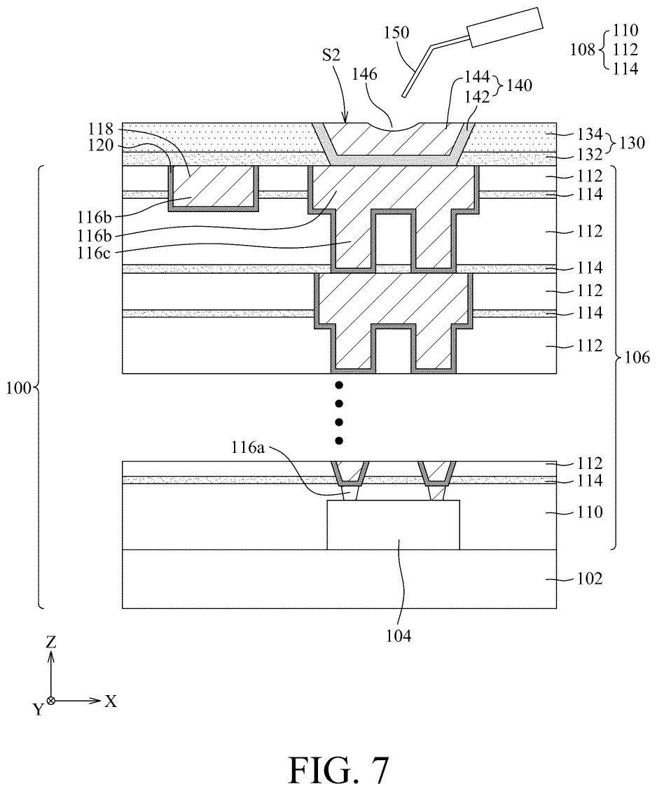

Referring to FIG. 7, an electrical test is performed to determine or verify a performance of the base structure 100. In some embodiments, during the electrical test, a probe 150 may be electrically connected to the conductive pad 140, such that an electrical signal may be applied to the base structure 100 so as to determine or verify an electrical performance of the first semiconductor chip. In some embodiments, the electrical test may be referred to as a chip probing test. In some embodiments, the electrical test includes an enhanced voltage stress (EVS) test. In order to prevent a poor contact between the probe 150 and the conductive pad 140, the probe 150 may be pressed against the conductive pad 140 by a force during the electrical test, thereby forming an indentation 146 (or a roughness) which is recessed from an upper surface S2 of the conductive filling portion 144 and which has a depth. In order to prevent the base structure 100 from being damaged by the probe 150, the conductive pad 140, before the electrical test, may be formed to have a sufficient thickness that is greater than the depth of the indentation 146, which may be caused by the probe 150 pressing against the conductive pad 140. In some embodiments, each of the passivation structure 130 and the conductive pad 140 has a first thickness (t1, see FIG. 6A) before the electrical test. The structure shown in FIG. 7 is obtained after step S04 of the method as shown in FIG. 1.

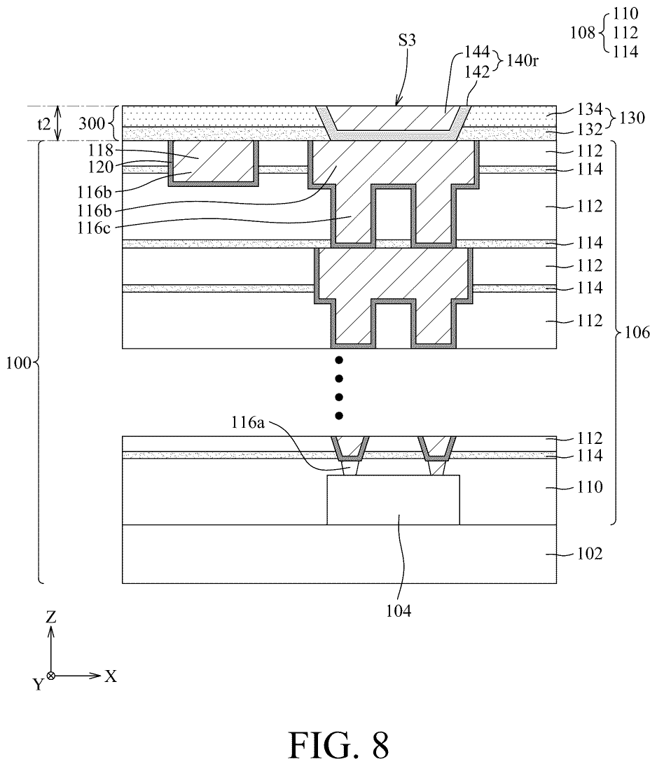

After the electrical test, a pad-processing treatment is performed on the conductive pad 140 to form a pad feature 140r in the passivation structure 130, as shown in FIG. 8. During the pad-processing treatment, the interconnect structure 106 is kept covered by the passivation structure 130 and the barrier portion 142 of the conductive pad 140. After the pad-processing treatment, the indentation 146 is eliminated. The passivation structure 130 and the pad feature 140r collectively constitute a protection structure 300. The protection structure 300 has a planar surface S3, which is beneficial to a subsequent bonding process (step S08).

In some embodiments, the pad-processing treatment includes subjecting the passivation structure 130 and the conductive pad 140 shown in FIG. 7 to a second planarization process so as to reduce the first thickness (t1) of each of the passivation structure 130 and the conductive pad 140 until the indentation 146 is eliminated. In such case, the protection structure 300 includes the passivation structure 130 and the conductive pad 140 each having a second thickness (t2) that is less than the first thickness (t1). The conductive pad 140, which has the second thickness (t2), serves as the pad feature 140r. The structure shown in FIG. 8 is obtained after step S05 of the method as shown in FIG. 1.

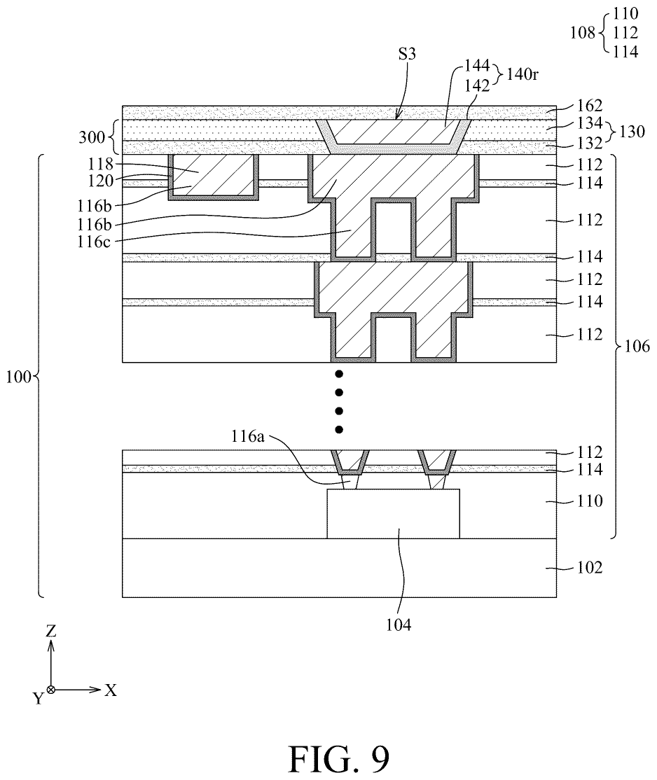

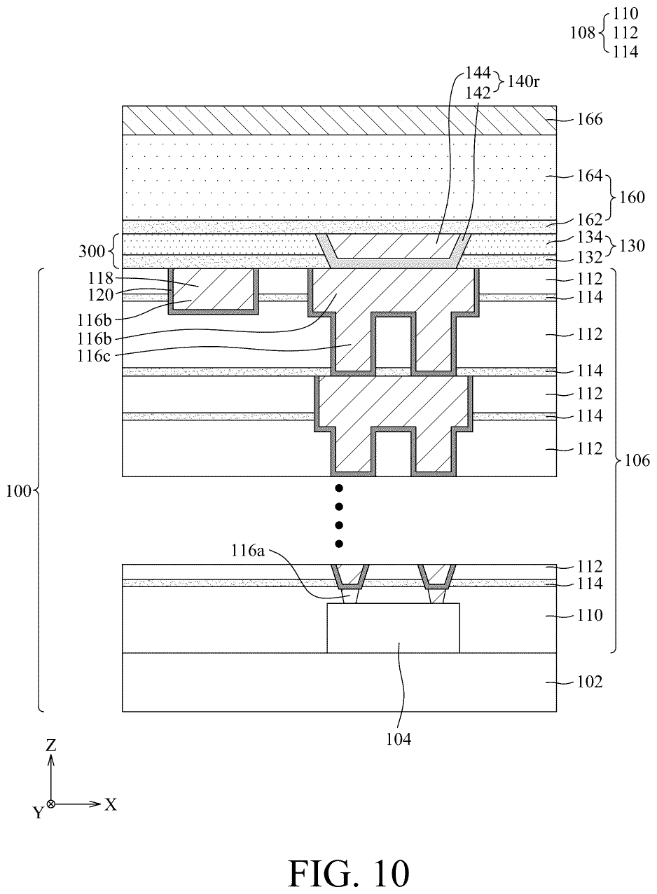

Referring to FIG. 9, a dielectric layer 162 is formed on the planar surface S3 of the protection structure 300 by CVD, ALD, PVD, or other suitable deposition techniques. Referring to FIG. 10, a dielectric layer 164 is formed on the dielectric layer 162 by CVD, ALD, PVD, or other suitable deposition techniques, followed by a planarization process to have a planar upper surface. In some embodiments, the dielectric layers 162, 164 collectively constitute a second dielectric portion 160. In some embodiments, a dielectric constant of the dielectric layer 162 is greater than a dielectric constant of the dielectric layer 164. Since possible dielectric materials suitable for the dielectric layer 162 are similar to those for forming the etch stop layers 114, and possible dielectric materials suitable for the dielectric layer 164 are similar to those for forming the ILD layer 110 and the IMD layer 112, details thereof are omitted for the sake of brevity. The structure shown in FIG. 10 is obtained after step S06 of the method as shown in FIG. 1. Still referring to FIG. 10, a hard mask layer 166 is formed on the dielectric layer 164 by CVD, ALD, PVD, or other suitable deposition techniques for a subsequent patterning process. 166. In some embodiments, the hard mask layer 166 includes or is made of silicon oxynitride, or other suitable dielectric materials.

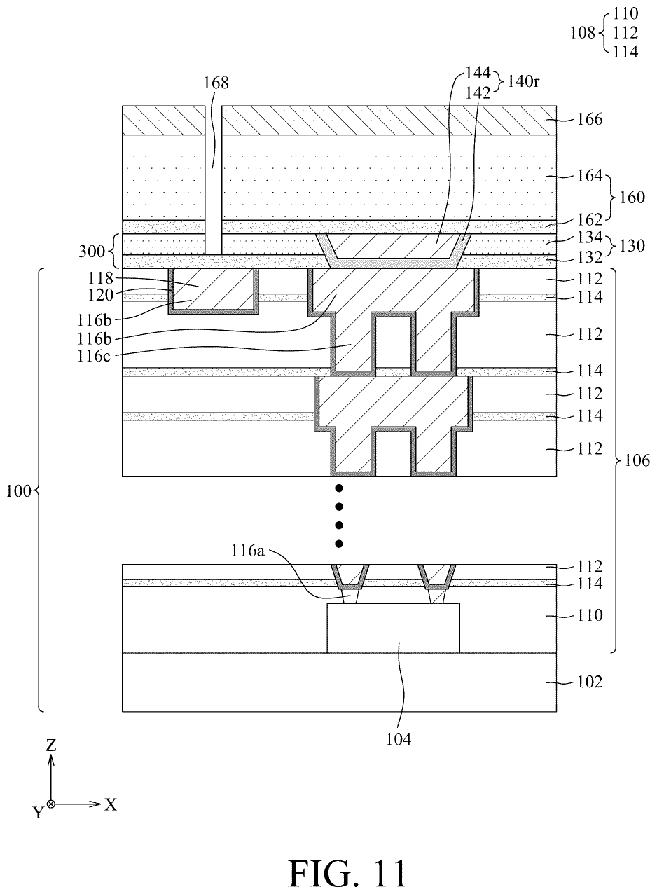

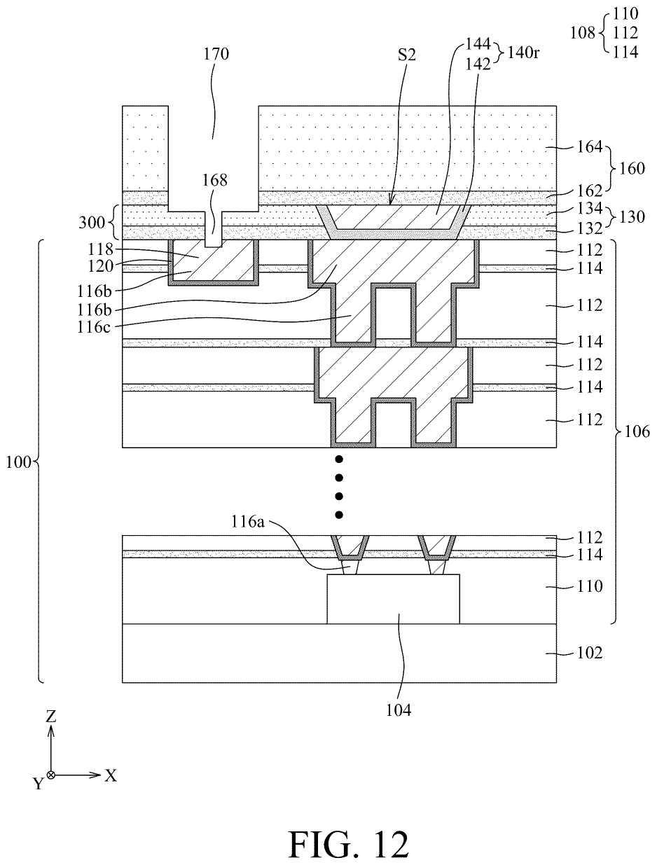

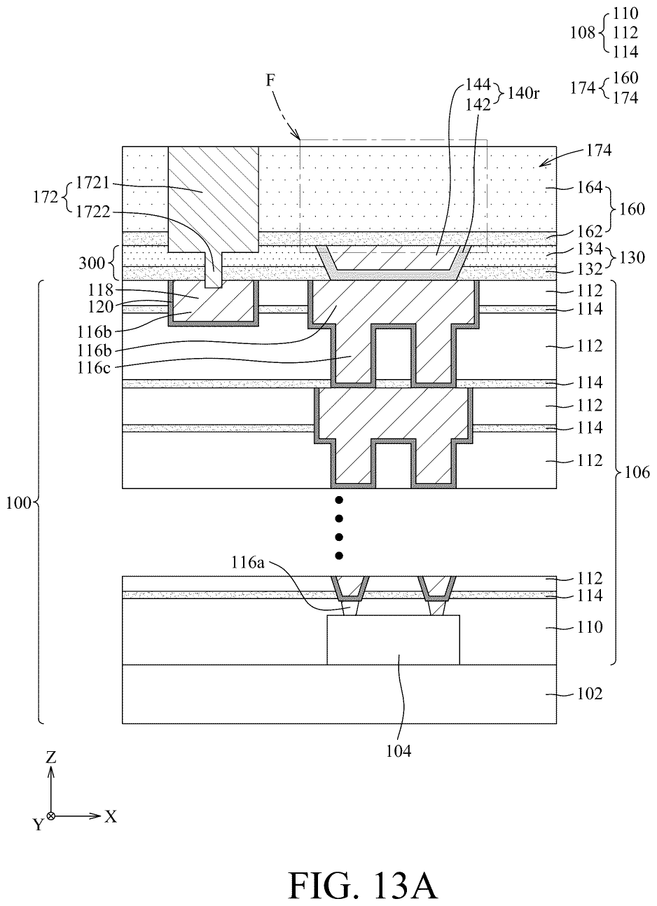

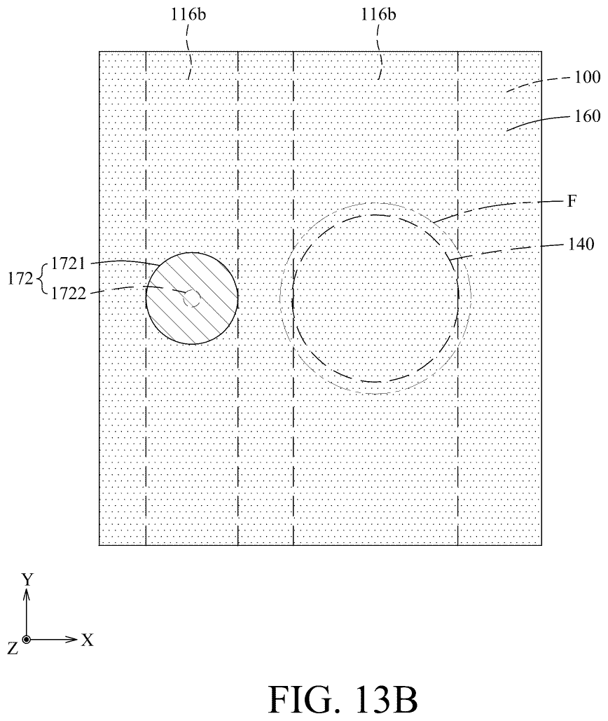

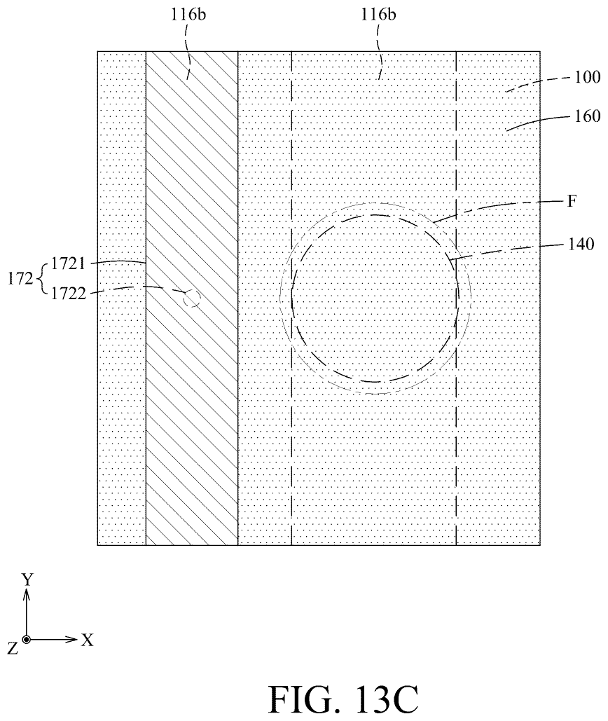

Referring to FIG. 11, a via opening 168 is formed to extend through the dielectric portion 160 into the protection structure 300 by a patterning process. In some embodiments, the via opening 168 terminates at the dielectric layer 132 of the passivation structure 130, so that a left one of the conductive lines 116b is prevented from being exposed to the via opening 168. Referring to FIG. 12, a recess 170 is formed in the dielectric portion 160 and is in spatial communication with the via opening 168. The recess 170 has a dimension that is greater than a dimension of the via opening 168. The recess 170 may be configured to form a conductive line, a conductive via, or a contact therein in subsequent deposition processes. In some embodiments, the hard mask layer 166 (see FIG. 11) may be consumed or removed during formation of the recess 170. After forming the recess 170, a portion of the dielectric layer 132 that is exposed to the via opening 168 is removed by an etching process so as to expose the left one of the conductive lines 116b. It is noted that the conductive pad 140 in the protection structure 300 is prevented from being exposed to the via opening 168 and the recess 170. In other words, the conductive pad 140 is spaced apart from the via opening 168 and the recess 170 by the passivation structure 130 and the dielectric portion 160. Referring to FIG. 13A, a conductive portion 172 is formed to fill the via opening 168 and the recess 170 by CVD, ALD, PVD, an electroplating process, an electroless-plating process, or other suitable deposition techniques. The conductive portion 172 extends through the dielectric portion 160 and the protection structure 300 so as to be electrically connected to the left one of the conductive lines 116b. Since possible conductive materials suitable for the conductive portion 172 are similar to those for forming the conductive filling portion 118, details thereof are omitted for the sake of brevity.

FIGS. 13B and 13C are each a schematic top view similar to that of FIG. 6B, but further illustrates the dielectric portion 160 and the conductive portion 172 in accordance with some different embodiments. In some embodiments, as shown in FIG. 13B, a first region 1721 of the conductive portion 172 that is formed in the dielectric portion 160 may be configured as a conductive via or a contact, and a second region 1722 of the conductive portion 172 that is formed in the protection structure 300 may be configured as another conductive via. In some other embodiments, as shown in FIG. 13C, the first region 1721 of the conductive portion 172 may be configured as a conductive line, and the second region 1722 of the conductive portion 172 may be configured as a conductive via.

As shown in FIG. 13A, the pad feature 140r extends from the right one of the conductive lines 116b, penetrates through the passivation structure 130, and terminates at an interface between the passivation structure 130 and the dielectric portion 160. The conductive portion 172 is spaced apart from the pad feature 140r by the passivation structure 130 and the dielectric portion 160. In some embodiments, the conductive portion 172 is prevented from being formed in a region of the dielectric portion 160 that is located directly above the conductive pad 140. Such region of the dielectric portion 160 may be referred to as a forbidden zone (labeled with a letter “F”), which is an area of a layout design in which conductive features/standard cells are not allowed to be placed. As shown in FIG. 13B or 13C, the shape of the forbidden zone (F) may be the same or similar to the shape of the pad feature 140r, and the size of the forbidden zone (F) may be not less than the size of the pad feature 140r. In some embodiments, a projection of the conductive portion 172 on the base structure 100 is separated from a projection of the conductive pad 140 on the base structure 100, as shown in FIGS. 13B and 13C. In some embodiments, the dielectric portion 160 and the conductive portion 172 may collectively constitute a first bonding layer 174. The structure shown in FIG. 13A is obtained after step S07 of the method as shown in FIG. 1.

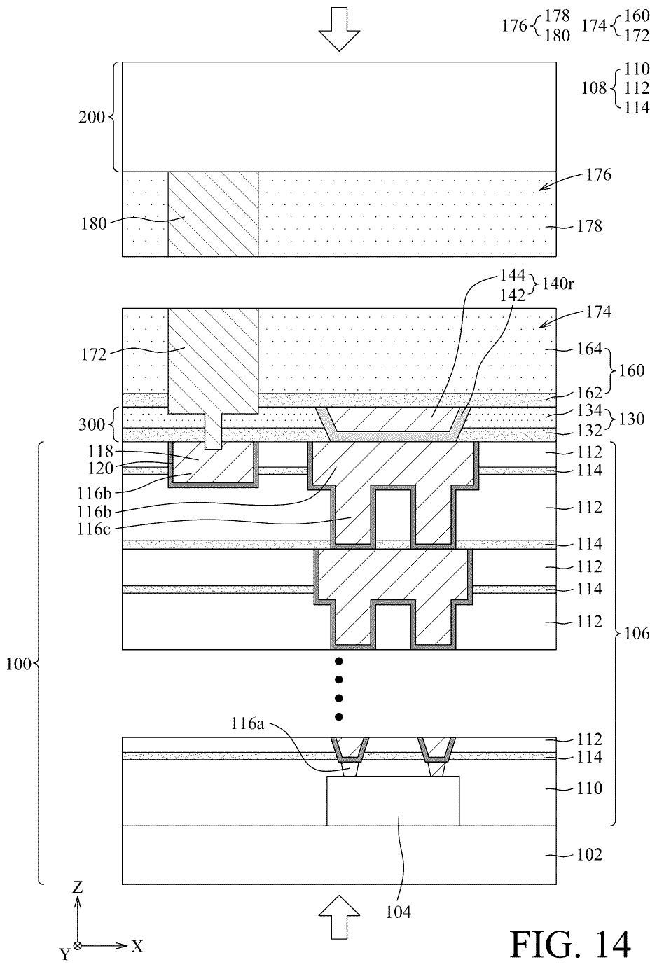

FIG. 14 is a schematic sectional view similar to that of FIG. 13A, but further illustrating a second base structure 200 in a second semiconductor chip in accordance with some embodiments. In some embodiments, the second semiconductor chip may be one of chips on a second wafer (the second wafer is not singulated), or a chip that is singulated from the second wafer. The second base structure 200 may have a structure similar to or different from that of the first base structure 100. As shown in FIG. 14, a second bonding layer 176 is formed on the second base structure 200. The second bonding layer 176 includes a dielectric portion 178 and a conductive portion 180 formed in the dielectric portion 178. Possible dielectric materials suitable for the dielectric portion 178 are similar to those for forming the dielectric layer 164, and possible conductive materials suitable for the conductive portion 180 are similar to those for forming the conductive portion 172. Furthermore, the second bonding layer 176 may be formed in a manner similar to that for forming the first bonding layer 174 as described above with reference to FIGS. 9 to 13A. Thus, details of formation and materials of the second bonding layer 176 are omitted for the sake of brevity. Next, referring to FIGS. 14 and 15, a bonding process is performed such that the first base structure 100 and the second base structure 200 are bonded to each other through the first bonding layer 174 and the second bonding layer 176, thereby obtaining the semiconductor structure 400 shown in FIG. 15. In the semiconductor structure 400, the dielectric portion 160 is bonded to the dielectric portion 178, and the conductive portion 172 is bonded to the conductive portion 180. In some embodiments, the bonding process includes a wafer-to-wafer bonding process. In some embodiments, no conductive feature is formed in a region (labeled with a letter “R”) of the dielectric portions 160, 178 that is located between the pad feature 140r and the second base structure 200. The structure shown in FIG. 15 is obtained after step S08 of the method as shown in FIG. 1.

FIG. 21 is a schematic sectional view similar to that of FIG. 15, but illustrating the semiconductor structure 400 in accordance with some other embodiments. Similar numerals from the above-mentioned embodiments have been used where appropriate, with some construction differences being indicated with different numerals. The semiconductor structure 400 shown in FIG. 21 has a structure similar to the semiconductor structure 400 shown in FIG. 15, but the conductive filling portion 144 of the pad feature 140r shown in FIG. 15 is replaced with a dielectric filling portion 145.

The semiconductor structure 400 shown in FIG. 21 may be formed in a manner similar to the method for manufacturing the semiconductor structure 400 shown in FIG. 15 as described above with reference to FIGS. 1 to 15, but has differences in formation of the conductive pad 140 (step S03) and the pad-processing treatment after the electrical test (step S05). Only the differences will be described in the following.

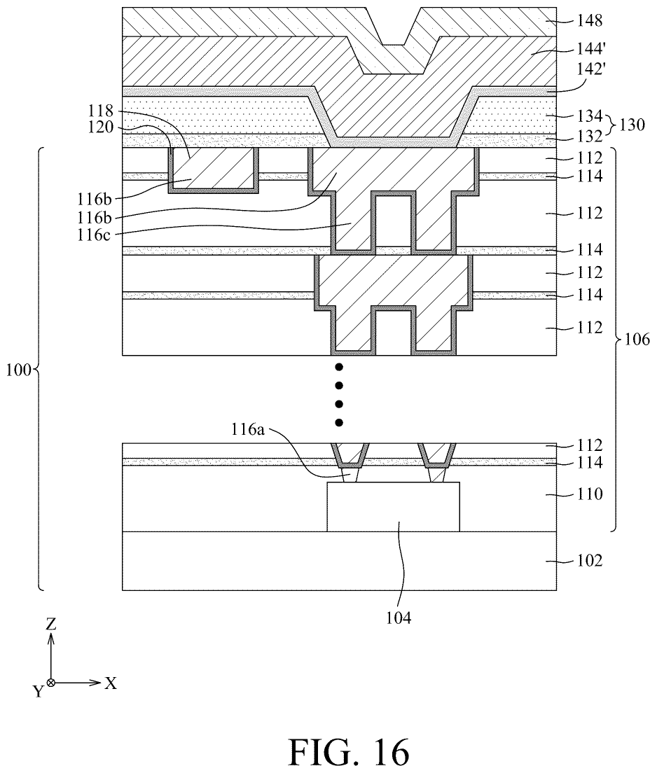

FIG. 16 is a schematic sectional view similar to that of FIG. 5, but illustrating a barrier layer 142′, a conductive layer 144′, and a hard mask layer 148 in accordance with some embodiments, in which the conductive layer 144′ shown in FIG. 16 may have a thickness that is less than a thickness of the conductive layer 144 shown in FIG. 5. Possible materials suitable for the hard mask layer 148 are similar to those for forming the hard mask layer 166 as described above with reference to FIG. 11. Possible materials suitable for the barrier layer 142′ are similar to those for forming the barrier layer 142. Possible conductive materials suitable for the conductive layer 144′ are similar to those for forming the conductive filling portion 144. Thus, details of the materials of the barrier layer 142′, the conductive layer 144′, and the hard mask layer 148 are omitted for the sake of brevity.

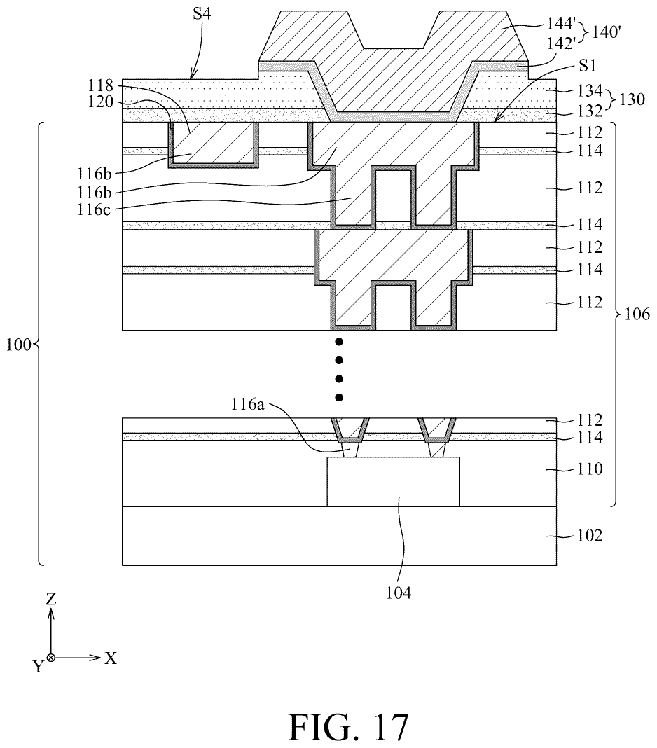

Referring to FIG. 17, the barrier layer 142′ and the conductive layer 144′ are patterned by a patterning process to form a conductive pad 140′ (step S03). In some embodiments, the hard mask layer 148 (see FIG. 16) may be consumed or removed during the patterning process for forming the conductive pad 140′. The conductive layer 144′ and the barrier layer 142′ are respectively patterned into a conductive portion (still denoted by the reference numeral 144′) and a barrier portion (still denoted by the reference numeral 142′) of the conductive pad 140′. The conductive pad 140′ covers a first portion of an upper surface S4 of the passivation structure 130 to expose a second portion of the upper surface S4 of the passivation structure 130. In some embodiments, an etching process in the patterning process for forming the conductive pad 140′ may be performed until the second portion of the upper surface S4 of the passivation structure 130 is exposed. In some embodiments, after the etching process, the upper surface S4 of the passivation structure 130 may have a stepped profile at a boundary between the first portion and the second portion of the upper surface S4.

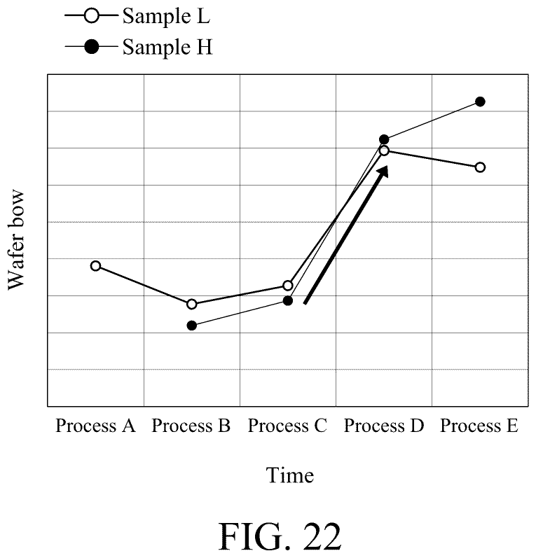

FIG. 22 is a graph illustrating the variation of wafer bow (or wafer warpage) under processes A to E for Sample L and Sample H for forming the semiconductor structure 400 in accordance with some embodiments. The wafer bow of each of Samples L and H is detected after one of the processes is completed and before proceeding to the next one of the processes. In Process A, the first and second dielectric layers 132, 134 of the passivation structure 130 is formed on the interconnect structure 106 (step S02, see FIG. 3). In Process B, the second dielectric layer 134 is patterned. In Process C, the first dielectric layer 132 is patterned to form the opening 136 in the passivation structure 130, such that the right one of the conductive lines 116b is exposed to the opening 136 (see FIG. 4). In Process D, the conductive layer 144′ is formed on the passivation structure 130 to fill the opening 136 (see FIG. 16). In Process E, the hard mask layer 148 is formed on the conductive layer 144′ (see FIG. 16). Process parameters in each of Processes A to E for forming each of Samples L and H are substantially the same, except that, in Process E, the hard mask layer 148 of Sample L is formed at a temperature that is lower than a temperature at which the hard mask layer 148 of Sample H is formed. As shown in FIG. 22, the wafer bow of each of Samples L and H significantly increases after formation of the conductive layer 144′ (Process D). Although the hard mask layer 148 of Sample L is formed at a relatively low temperature, the warpage of Sample L after formation of the hard mask layer 148 (Process E) is relatively high in compassion with the warpage of Sample L before formation of the conductive layer 144′ (Process D). The warpage of the structure shown in FIG. 16 may induce a stress in the interconnect structure 106. The stress in the interconnect structure 106 may have a maximum value at an interface between the passivation structure 130 and the interconnect structure 106, and gradually decreases toward the substrate 102. Furthermore, it is presumed that once the passivation structure 130 is removed to expose the interconnect structure 106, a gradient of the stress in the interconnect structure 106 may be changed, and thus defects (e.g., copper pits defects) may be formed at the upper surface S1 of the interconnect structure 106. Therefore, in order to reduce defects formed in the interconnect structure 106, the interconnect structure 106 is kept covered by the passivation structure 130 and the barrier portion 142′ of the conductive pad 140′ during the pad-processing treatment (step S05) for removing an indentation formed in the conductive portion 144′ of the conductive pad 104′.

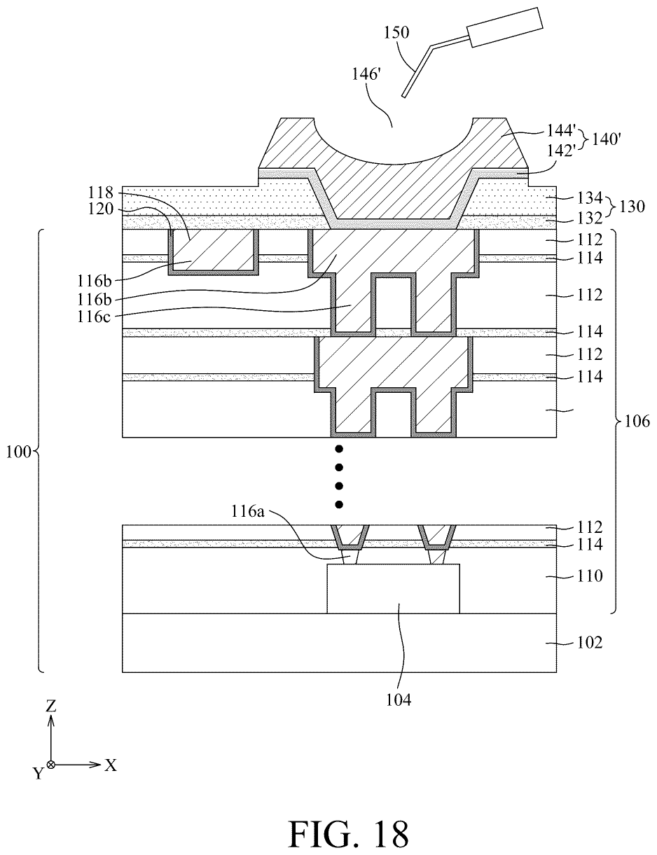

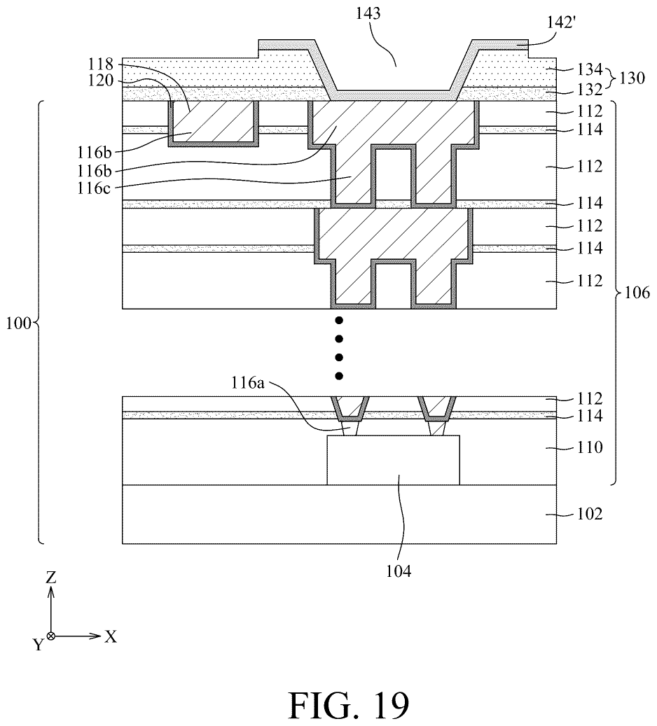

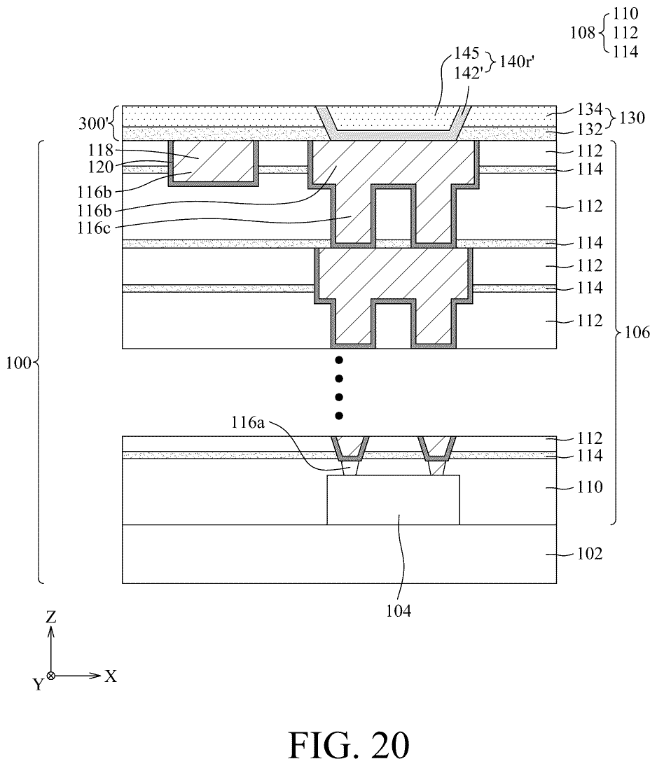

FIG. 18 is a schematic sectional view similar to that of FIG. 17, but illustrating an indentation 146′ which is formed in the conducive portion 144′ of the conductive pad 140′ during the electrical test (step S04). After the electrical test, the pad-processing treatment (step S05) is performed on the structure shown in FIG. 18 in a manner as described in the following with reference to FIGS. 19 and 20.

Referring to FIG. 19, the conductive portion 144′ of the conductive pad 140′ is removed to form a recess 143 defined by the barrier portion 142′, and the barrier portion 142′ is left on the right one of the conductive lines 116b, so as to prevent the right one of the conductive lines 116b from being exposed to the recess 143.

Referring to FIG. 20, the dielectric filling portion 145 is formed in the recess 143 by CVD, ALD, PVD, or other suitable deposition techniques, followed by a planarization process to expose the passivation structure 130, thereby obtaining a pad feature 140r′ formed in the passivation structure 130. During the pad-processing treatment, the interconnect structure 106 is kept covered by the passivation structure 130 and the barrier portion 142′ of the conductive pad 140′. After the pad-processing treatment, the indentation 146′ is eliminated. The passivation structure 130 and the pad feature 140r′ collectively constitute a protection structure 300′ which remains on the interconnect structure 106. Since possible dielectric materials suitable for the dielectric filling portion 145 are similar to those for forming the ILD layer 110 and the IMD layer 112, details thereof are omitted for the sake of brevity.

The protection structure 300′ has a structure that is similar to that of the protection structure 300 shown in FIG. 8, but the conductive filling portion 144 is replaced with the dielectric filling portion 145. That is, the protection structure 300′ includes the passivation structure 130, the dielectric filling portion 145 which is disposed in the passivation structure 130, and the barrier layer 142′ which is disposed to separate the dielectric filling portion 145 from the passivation structure 130 and the right one of the conductive lines 116b.

In some embodiments not shown herein, the pad-processing treatment (step S05) that is performed on the structure shown in FIG. 18 may include an etching process and/or a planarization process so as to eliminate the indentation 146′, thereby obtaining a protection structure (such as the protection structure 300 shown in FIG. 8) which has a planar upper surface and which remains on the interconnect structure 106 so as to prevent the interconnect structure 106 from being exposed.

In some embodiments not shown herein, the structure shown in FIG. 7 may be not subjected to the pad-processing treatment as described above with reference to FIG. 8, but is subjected to the pad-processing treatment as described above with reference to FIGS. 19 and 20, thereby obtaining structure shown in FIG. 20.

Afterwards, the dielectric portion 160 (step S06) and the conductive portion 172 (step S07) may be formed in a manner similar to that as described above with reference to FIGS. 9 to 13A, and thus details thereof are omitted for the sake of brevity.

FIG. 21 is a schematic sectional view similar to that of FIG. 20, but illustrating the structure after the bonding process (step S08). The bonding process may be performed in a manner similar to that as described above with reference to FIGS. 14 and 15, and thus details thereof are omitted for the sake of brevity.

In some alternative embodiments, the semiconductor structure 400 may further include additional features, and/or some features present in the semiconductor structure 400 may be modified, replaced, or eliminated without departure from the spirit and scope of the present disclosure.

In summary, the semiconductor structure 400 obtained by the method of the present disclosure may have the pad feature 140r or 140r′ present in the semiconductor structure 400. Since the interconnect structure 106 is kept covered by the passivation structure 130 and the barrier portion 142 or 142′ of the conductive pad 140 or 140′ during the pad-processing treatment for removing the indentation 146 or 146′, the reliability performance of the semiconductor structure 400 may be significantly enhanced due to reduction of defects in the interconnect structure 106.

In accordance with some embodiments of the present disclosure, a method for manufacturing a semiconductor structure includes: forming a base structure, the base structure including a device region and an interconnect structure formed over the device region, the interconnect structure including a plurality of interconnect layers formed in a dielectric layer and connected to the device region, each of the interconnect layers including metal lines, at least one of the metal lines including a curved top surface, the curved top surface being above a top surface of the dielectric layer that is formed around the metal lines; forming a passivation structure on the interconnect structure; forming a conductive pad which extends through the passivation structure so that the conductive pad is connected to a first portion of the interconnect layers; performing an electrical test on the base structure through the conductive pad; after the electrical test, performing a pad-processing treatment on the conductive pad to form a pad feature in the passivation structure; forming a dielectric portion on the passivation structure and the pad feature; and forming a conductive portion which extends through the dielectric portion and the passivation structure so that the conductive portion is connected to a second portion of the interconnect layers.

In accordance with some embodiments of the present disclosure, the pad-processing treatment includes performing a planarization process on the passivation structure and the conductive pad to reduce a thickness of each of the passivation structure and the conductive pad. The conductive pad with a reduced thickness serves as the pad feature.

In accordance with some embodiments of the present disclosure, a projection of the conductive portion on the base structure is separated from a projection of the pad feature on the base structure.

In accordance with some embodiments of the present disclosure, formation of the conductive pad includes: forming an opening in the passivation structure to expose the first portion of the interconnect layers; forming a conductive layer on the passivation structure to fill the opening; and performing a planarization process on the conductive layer to expose the passivation structure, such that the conductive layer is formed into the conductive pad.

In accordance with some embodiments of the present disclosure, formation of the conductive pad includes: forming an opening in the passivation structure to expose the first portion of the interconnect layers; forming a conductive layer on the passivation structure to fill the opening; and patterning the conductive layer such that the conductive layer is formed into the conductive pad. The conductive pad covers a first portion of an upper surface of the passivation structure to expose a second portion of the upper surface of the passivation structure.

In accordance with some embodiments of the present disclosure, a method for manufacturing a semiconductor structure includes: forming a first base structure, the first base structure including a plurality of transistors, and an interconnect structure formed over the plurality of transistors, the interconnect structure having an upper surface, the interconnect structure including a plurality of dielectric layers interleaved by etch stop layers, and a plurality of metal lines disposed in the plurality of dielectric layers and electrically connected to the plurality of transistors, a farthest one of the plurality of metal lines relative to the plurality of transistors having a portion of the upper surface of the interconnect structure; forming a passivation structure on the upper surface of the interconnect structure; forming a conductive pad which extends through the passivation structure so that the conductive pad is connected to a first portion of the farthest one of the plurality of metal lines; performing an electrical test on the first base structure through the conductive pad; after performing the electrical test, performing a pad-processing treatment on the conductive pad to form a pad feature in the passivation structure; forming a first dielectric portion on the passivation structure and the pad feature; and forming a first conductive portion which extends through the second dielectric portion and the passivation structure so that the first conductive portion is connected to a second portion of the farthest one of the plurality of metal lines.

In accordance with some embodiments of the present disclosure, the first conductive portion is separated from the pad feature by the first dielectric portion and the passivation structure.

In accordance with some embodiments of the present disclosure, the passivation structure includes a first dielectric layer formed on the interconnect structure and a second dielectric layer formed on the first dielectric layer opposite to the interconnect structure. A dielectric constant of the first dielectric layer is greater than a dielectric constant of the second dielectric layer.

In accordance with some embodiments of the present disclosure, the conductive pad includes a barrier portion and a conductive filling portion. The barrier portion is disposed to separate the conductive filling portion from the passivation structure and the farthest one of the plurality of metal lines.

In accordance with some embodiments of the present disclosure, during the pad-processing treatment, the interconnect structure is covered by the passivation structure and the barrier portion of the conductive pad.

In accordance with some embodiments of the present disclosure, the pad-processing treatment includes: removing the conductive filling portion to form a recess, while leaving the barrier portion on the first portion of the conductive line, so as to prevent the first portion of the conductive line from being exposed to the recess defined by the barrier portion; and forming a dielectric filling portion in the recess. The dielectric filling portion and the barrier portion collectively serve as the pad feature.

In accordance with some embodiments of the present disclosure, the first portion of the farthest one of the plurality of metal lines extends lengthwise along a first direction, and has a length along the first direction and a width along a second direction transverse to the first direction. A bottom of the conductive pad has a first dimension along the first direction and a second dimension along the second direction. The first dimension is less than the length of the conductive line. The second dimension (d2) is not greater than the width of the conductive line.

In accordance with some embodiments of the present disclosure, the first conductive portion includes a first portion which is formed in the first dielectric portion and which is configured as a conductive line, and a second portion which is formed in the passivation structure and which is configured as a conductive via.

In accordance with some embodiments of the present disclosure, the first dielectric portion and the first conductive portion collectively serve as a first bonding layer which is formed on the first base structure. the method further includes: forming a second bonding layer on a second base structure, the second bonding layer including a second dielectric portion and a second conductive portion formed in the second dielectric portion; and performing a bonding process such that the first base structure and the second base structure are bonded to each other through the first bonding layer and the second bonding layer. The first dielectric portion is bonded to the second dielectric portion, and the first conductive portion is bonded to the second conductive portion.

In accordance with some embodiments of the present disclosure, the bonding process includes a wafer-to-wafer bonding process.

In accordance with some embodiments of the present disclosure, a semiconductor structure includes: a plurality of transistors; an interconnect structure disposed over the plurality of transistors, the interconnect structure having an upper surface, the interconnect structure including a plurality of dielectric layers, a thickness of a bottommost one of the plurality of dielectric layers being less than a thickness of at least one of the plurality of dielectric layers above the bottommost one of the plurality of dielectric layers, and interconnect layers disposed in the plurality of dielectric layers and electrically connected to the plurality of transistors, a farthest one of the interconnect layers relative to the plurality of transistors having a portion of the upper surface of the interconnect structure; a passivation structure disposed on the upper surface of the interconnect structure; a dielectric portion disposed on the passivation structure; a pad feature which extends from a first portion of the farthest one of the interconnect layers, penetrates through the passivation structure, and terminates at an interface between the passivation structure and the dielectric portion; and a conductive portion which extends through the dielectric portion and the passivation structure so that the conductive portion is connected to a second portion of the farthest one of the interconnect layers.

In accordance with some embodiments of the present disclosure, a projection of the conductive portion on the base structure is separated from a projection of the pad feature on the base structure.

In accordance with some embodiments of the present disclosure, the pad feature includes a barrier portion and a conductive filling portion. The barrier portion is disposed to separate the conductive filling portion from the passivation structure and the first portion of the farthest one of the interconnect layers.

In accordance with some embodiments of the present disclosure, the pad feature includes a barrier portion and a dielectric filling portion. The barrier portion is disposed to separate the dielectric filling portion from the passivation structure and the first portion of the farthest one of the interconnect layers.

In accordance with some embodiments of the present disclosure, the farthest one of the interconnect layers includes conductive lines.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for manufacturing a semiconductor structure, comprising:
depositing a passivation structure on an interconnect structure of a base structure, the base structure including
a device region, and
the interconnect structure disposed over the device region and including a plurality of interconnect layers disposed in a dielectric layer and connected to the device region, each of the plurality of interconnect layers including metal lines, at least one of the metal lines including a curved top surface, the curved top surface being above a top surface of the dielectric layer that is disposed around the metal lines;
patterning the passivation structure to form a first opening, such that a first portion of the interconnect layers is exposed to the first opening;
filling the first opening with a conductive pad, such that the conductive pad is connected to the first portion of the interconnect layers;
performing an electrical test on the base structure through the conductive pad;
after the electrical test, performing a pad-processing treatment on the conductive pad to form a pad feature in the passivation structure;
depositing a dielectric portion on the passivation structure and the pad feature;
patterning the dielectric portion and the passivation structure to form a second opening, such that a second portion of the interconnect layers is exposed to the second opening; and
filling the second opening with a conductive portion, such that the conductive portion is connected to the second portion of the interconnect layers.

2. The method as claimed in claim 1, wherein the pad-processing treatment includes performing a planarization process on the passivation structure and the conductive pad to reduce a thickness of each of the passivation structure and the conductive pad, the conductive pad with a reduced thickness serving as the pad feature.

3. The method as claimed in claim 1, wherein a projection of the conductive portion on the base structure is separated from a projection of the pad feature on the base structure.

4. The method as claimed in claim 1, wherein filling the first opening with the conductive pad includes
depositing a conductive layer on the passivation structure to fill the first opening, and
performing a planarization process on the conductive layer to expose the passivation structure, such that the conductive layer is formed into the conductive pad.

5. The method as claimed in claim 1, wherein filling the first opening with of the conductive pad includes
depositing conductive layer on the passivation structure to fill the first opening, and
patterning the conductive layer such that the conductive layer is formed into the conductive pad, the conductive pad covering a first portion of an upper surface of the passivation structure to expose a second portion of the upper surface of the passivation structure.

6. A method for manufacturing a semiconductor structure, comprising:
depositing a passivation structure on a first base structure, the first base structure including
a plurality of transistors, and
an interconnect structure disposed over the plurality of transistors, the interconnect structure having an upper surface, the interconnect structure including
a plurality of dielectric layers interleaved by etch stop layers, and
a plurality of metal lines disposed in the plurality of dielectric layers and electrically connected to the plurality of transistors, a farthest one of the plurality of metal lines relative to the plurality of transistors having a portion of the upper surface of the interconnect structure;
defining a first opening in the passivation structure to expose a first portion of the farthest one of the plurality of metal lines;
filling the first opening with a conductive pad, such that the conductive pad is connected to the first portion of the farthest one of the plurality of metal lines;
performing an electrical test on the first base structure through the conductive pad;
after performing the electrical test, performing a pad-processing treatment on the conductive pad to form a pad feature in the passivation structure;
depositing a first dielectric portion on the passivation structure and the pad feature;
defining a second opening in the first dielectric portion and the passivation structure to expose a second portion of the farthest one of the plurality of metal lines; and
filling the second opening with a first conductive portion, such that the first conductive portion is connected to the second portion of the farthest one of the plurality of metal lines.

7. The method as claimed in claim 6, wherein the first conductive portion is separated from the pad feature by the first dielectric portion and the passivation structure.

8. The method as claimed in claim 6, wherein the passivation structure includes a first dielectric layer formed on the interconnect structure and a second dielectric layer formed on the first dielectric layer opposite to the interconnect structure, a dielectric constant of the first dielectric layer being greater than a dielectric constant of the second dielectric layer.

9. The method as claimed in claim 6, wherein the conductive pad includes a barrier portion and a conductive filling portion, the barrier portion being disposed to separate the conductive filling portion from the passivation structure and the farthest one of the plurality of metal lines.

10. The method as claimed in claim 9, wherein during the pad-processing treatment, the interconnect structure is covered by the passivation structure and the barrier portion of the conductive pad.

11. The method as claimed in claim 10, wherein
the pad-processing treatment includes
removing the conductive filling portion to form a recess, the barrier portion being left on the first portion of the conductive line, so as to prevent the first portion of the conductive line from being exposed to the recess defined by the barrier portion, and
filling the recess with a dielectric filling portion, the dielectric filling portion and the barrier portion collectively serving as the pad feature.

12. The method as claimed in claim 6, wherein
the first portion of the farthest one of the plurality of metal lines extends lengthwise along a first direction, and has a length along the first direction and a width along a second direction transverse to the first direction, and
a bottom of the conductive pad has a first dimension along the first direction and a second dimension along the second direction, the first dimension being less than the length of the conductive line, the second dimension being not greater than the width of the conductive line.

13. The method as claimed in claim 6, wherein the first conductive portion includes
a first portion which is formed in the first dielectric portion and which is configured as a conductive line, and
a second portion which is formed in the passivation structure and which is configured as a conductive via.

14. The method as claimed in claim 6, wherein
the first dielectric portion and the first conductive portion collectively serve as a first bonding layer which is formed on the first base structure, and
the method further comprises:
depositing a second bonding layer on a second base structure, the second bonding layer including a second dielectric portion and a second conductive portion formed in the second dielectric portion; and
performing a bonding process such that the first base structure and the second base structure are bonded to each other through the first bonding layer and the second bonding layer, the first dielectric portion being bonded to the second dielectric portion, the first conductive portion being bonded to the second conductive portion.

15. The method as claimed in claim 14, wherein the bonding process includes a wafer-to-wafer bonding process.

16. A semiconductor structure, comprising:
a plurality of transistors;
an interconnect structure disposed over the plurality of transistors, the interconnect structure having an upper surface, the interconnect structure including
a plurality of dielectric layers, a thickness of a bottommost one of the plurality of dielectric layers being less than a thickness of at least one of the plurality of dielectric layers above the bottommost one of the plurality of dielectric layers, and
interconnect layers disposed in the plurality of dielectric layers and electrically connected to the plurality of transistors, a farthest one of the interconnect layers relative to the plurality of transistors having a portion of the upper surface of the interconnect structure;
a passivation structure disposed on the upper surface of the interconnect structure;
a dielectric portion disposed on the passivation structure;
a pad feature which extends from a first portion of the farthest one of the interconnect layers, penetrates through the passivation structure, and terminates at an interface between the passivation structure and the dielectric portion; and
a conductive portion which extends through the dielectric portion and the passivation structure so that the conductive portion is connected to a second portion of the farthest one of the interconnect layers.

17. The semiconductor structure as claimed in claim 16, wherein a projection of the conductive portion on the base structure is separated from a projection of the pad feature on the base structure.

18. The semiconductor structure as claimed in claim 16, wherein the pad feature includes a barrier portion and a conductive filling portion, the barrier portion being disposed to separate the conductive filling portion from the passivation structure and the first portion of the farthest one of the interconnect layers.

19. The semiconductor structure as claimed in claim 16, wherein the pad feature includes a barrier portion and a dielectric filling portion, the barrier portion being disposed to separate the dielectric filling portion from the passivation structure and the first portion of the farthest one of the interconnect layers.

20. The semiconductor structure as claimed in claim 16, wherein the farthest one of the interconnect layers includes conductive lines.
